(19) United States
(12) Patent Application Publication
(10) Pub. No.: US 2009/0111274 A1
(43) Pub. Date: Apr. 30, 2009

(54) Methods of Manufacturing a Semiconductor Device and Apparatus and Etch Chamber for the Manufacturing of Semiconductor Devices

(76) Inventor: Christoph Noelscher, Nuernberg (DE)

Correspondence Address: SLATER & MATSIL, L.L.P., 17950 PRESTON ROAD, SUITE 1000, DALLAS, TX, 75252, US

(21) Appl. No.: 11/930,394

(22) Filed: Oct. 31, 2007

(51) Int. Cl. H01L 21/3065; H01L 21/67

(52) U.S. Cl. 438/705; 156/345.55; 257/E21.218

(57) ABSTRACT

Methods of manufacturing a semiconductor device, apparatus and etch chamber for the manufacturing of semiconductor devices are provided. Embodiments are related to the rotating of a semiconductor substrate round an axis perpendicular to its surface during etching or reactive deposition processes, and irradiating a semiconductor substrate non-uniformly during etching or reactive deposition processes.

### TECHNICAL FIELD

Embodiments of the present invention generally relate to the manufacturing of semiconductor devices.

### BACKGROUND

In semiconductor manufacturing, etching is conducted to transfer a photoresist pattern to the underlying layer. By means of fine-tuning of lithography and etching parameters, a desired critical dimension (CD) can be achieved.

There is a general desire to provide for a uniform etching of a semiconductor wafer. Similarly, there is a general desire to provide for a uniform deposition in reactive wafer deposition processes.

### BRIEF DESCRIPTION OF THE DRAWINGS

The drawings show different exemplary embodiments and are not to be interpreted to limit the scope of the invention.

FIG. 1 schematically shows a first embodiment of an apparatus for the manufacturing of semiconductor devices;

FIG. 2 schematically shows a second embodiment of an apparatus for the manufacturing of semiconductor devices; and

FIG. 3 schematically shows the radial scanning of a rotating semiconductor wafer with electromagnetic radiation.

### DETAILED DESCRIPTION OF ILLUSTRATIVE EMBODIMENTS

The Figures show exemplary embodiments of apparatus and systems which comprise a wafer that is rotating during etching around an axis perpendicular to its surface. In one embodiment, the rotation of the wafer is around the center axis of the wafer. This results in a rotational symmetry of the etch rate. Even if the rotation axis is not through the wafer center, an increased uniformity is provided for by the rotational movement.

In a further aspect, the wafer is irradiated non-uniformly by electromagnatic radiation or particle radiation. The radiation is provided to compensate for a non-uniform etch rate that would be present without the additional radiation. Such non-uniformity may be premeasured or measured in-situ.

In one embodiment, both rotation of the wafer and the application of electromagnetic or particle radiation are provided for. In such an embodiment, a wafer rotation results in a rotational symmetry. A remaining radial nonuniformity in etch rate is reduced or eliminated by the non-uniform application of radiation. This way a uniform etch rate over the entire wafer can be achieved. Etch rate in this disclosure may mean both vertical etch rate and lateral etch rate, such that the resulting profiles are uniform over the wafer.

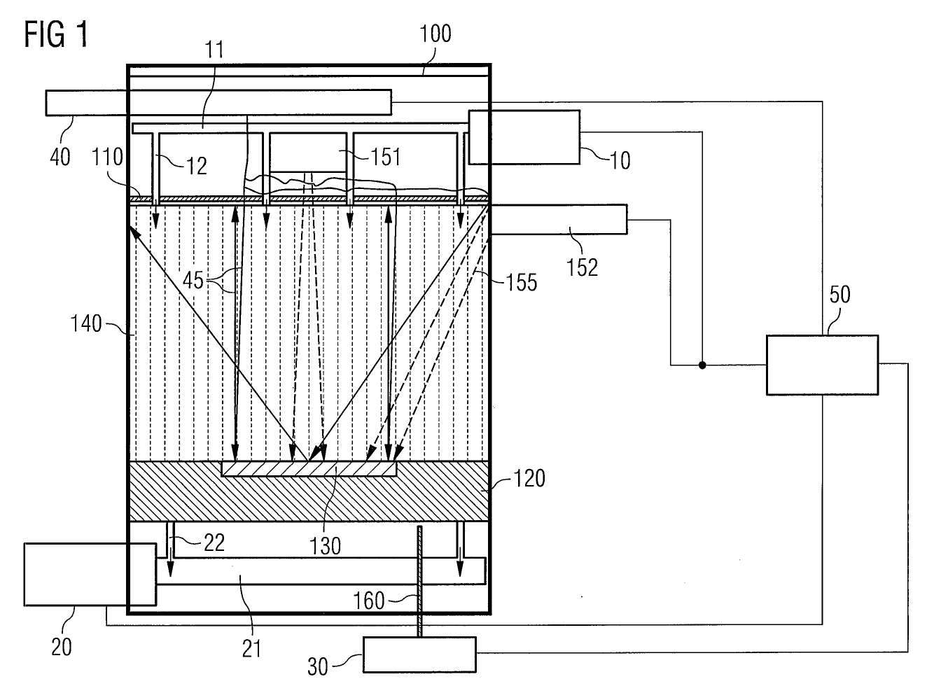

Attention is now drawn to FIG. 1, which shows an etch chamber 100 used in the process of manufacturing a semiconductor device. The etch chamber 100 comprises a chuck 120 supporting a semiconductor wafer 130. The chuck 120 also forms a lower electrode which is parallel to an upper electrode 110 of the etch chamber 100. Inside the etch chamber 100 and between electrodes 110, 120 is a gas plasma 140.

There is further provided a gas supply system 10 and a gas recycling/exhaust system 20. The gas supply system 10 is connected to a supply pipe 11 which, through inlet pipes 12, provides gas to the etch chamber 100. Similarly, gas from the etch chamber 100 is guided through outlet pipes 22 and an exhaust pipe 21 to gas recycling/exhaust system 20. Gas recycling/exhaust system 20 may include a vacuum pump.

There are provided several irradiation sources 151, 152, which directly illuminate the wafer 130, as is illustrated by dashed illumination arrows 155. The radiation of the irradiation sources 151, 152 may be infrared or optical light. In other embodiments, the radiation may be ultraviolet or deep ultraviolet as will be further explained below. In still other embodiments the radiation may be particle radiation such as electrons. The number of illumination sources 151, 152 may vary dependent on the kind and strength of the illumination sources and is depicted only exemplary in FIG. 1. Also, the irradiation sources 151, 152 may be an array of individual sources and may be separately controlled in intensity and or direction. The irradiation sources 151, 152 are arranged at the wall chamber and/or at the upper electrode 110.

It is pointed out that when radiation is discussed in this specification, radiation different from the radiation provided by the gas plasma 140 of the etch chamber 100 is meant.

The inner wall of the etch chamber 100 and/or the electrodes 110, 120 may comprise an antireflective coating.

The chuck 120 is connected to a rotatable axis 160 which is connected to a power supply and rotator 30. The rotator 30 rotates the chuck and thus also the wafer 130 around axis 160 during etching, e.g., by means of a gearbox. In FIG. 1, axis 160 is excentric to the central axis of the wafer 130. In other embodiments of FIG. 1, axis 160 is identical to the central axis of the wafer 130.

The system depicted in FIG. 1 may also comprise an in-situ etch rate measurement unit 40 adapted to measure the etch rate during etching. The etch rate measurement unit 40 may include standard optical measurement or infrared sensors like a heat image camera. Measurement signals of etch rate measurement unit 40 are illustrated by arrows 45.

In one embodiment, the etch rate measurement unit 40 may be a local in-situ film thickness measurement unit. In the simplest case, light of one wavelength is emitted that is reflected at one layer only that is located above an intransparent layer, whereby the reflected intensity modulo a fourth wavelength is a measure for the thickness of the layer. The unit thus works as a reflectometer. Generally, several wavelengths may be used for measuring the thickness of several layers. The changing thickness of a layer or layers is a measure for the etch rate.

The system further comprises a control system 50 electrically connected to the power supply and rotator 30, the irradiation sources 151, 152, the gas supply system 10, the gas recycling/exhaust system 20 and the etch rate measurement unit 40. The control system 50 may be implemented by a computer configured to control and coordinate the functions of the respective elements of the etch chamber 100.

The etch chamber of FIG. 1 implements a direct/top-down illumination of the wafer 130. This has the advantage of low shadows. At the same time, a relatively large distance between the irradiation sources 151, 152 and the wafer 130 and thus a relatively large volume is present.

In operation, a strong radio frequency electromagnetic field is created between the two electrodes 110, 120. The oscillating electric field ionizes the gas molecules by stripping them of electrons, creating a plasma. Such operation is well known to the skilled person and will thus not be further discussed.

The etching implemented in etch chamber 100 may be plasma etching, reactive ion etching or ion etching, although not limited to these.

The irradiation sources 151, 152 are configured to irradiate or illuminate the wafer 130 non-uniformly during etching to compensate for a non-uniform etch rate that would be present without the irradiation sources 151, 152. More particularly, electromagnetic or particle radiation is provided to the wafer 130 non-uniformly to enhance the etch rate. The radiation is applied with different intensities at areas of the wafer 130 in which the etch rate is lower than in other areas.

The signature of the etching process may be premeasured or determined by in-situ etch rate measurement unit 40 at different positions of the wafer. However, premeasurement of the signature or in-situ measurement is optional only and may be refrained from as part of the non-uniformity of the etch rate may be systematic. For example, after etching there often is a signature in critical dimension uniformity (CDU) from the wafer center to the wafer edge that corresponds to a non-uniform etch rate. A more uniform etching improves the critical dimension uniformity (CDU) which is usually lower after etching than after lithography.

As mentioned before, the radiation of irradiation sources 151, 152 may be infrared or optical light. Such wavelengths are used to heat the wafer locally differently and, by such heating, improve the etch rate.

In another embodiment, the radiation of irradiation sources 151, 152 may be ultraviolet (UV) or deep ultraviolet (DUV) light. Such wavelengths are used to bring electrons in a higher activated state to directly accelerate at least one of the reactions in the etch chamber 100, or the local ionization. Activated molecules or atoms are more reactive or enhance ionization of the plasma.

The rotation of the wafer during etching provides for a rotational symmetry of the etch rate. The wafer is rotating, e.g., with a rotational speed of at least about 3 rpm or at least about 5 rpm.

A remaining asymmetry in the radial direction may be addressed by the non-uniform application of radiation by irradiation sources 151, 152 as discussed above. Accordingly, in one embodiment, the intensity of radiation applied by irradiation sources 151, 152 is a function of the radial distance to the center of the wafer 130.

It is thus described a rotation of the wafer 130 during etching in combination with irradiation by electromagnetic or particle radiation such that a uniform etching is achieved.

In a further embodiment, a temperature controlled chuck 120 is used to maintain the wafer 130 at a predetermined basic temperature. To this end, the chuck 120 is thermally coupled to a cooling/heating part (not shown). To achieve etch uniformity, the cooling/heating part of the chuck in such a case is not rotated at all or not rotated at the same frequency as the wafer 130. Accordingly, i.e., proximity heating or proximity cooling of the chuck 120 is applied, or a temperature control fluid is used that is in direct contact with the wafer. Such fluid may be flowing through inlets/outlets in the non-rotating or less-rotating cooling/heating part. If the cooling/heating part of the chuck rotated at the same frequency as the wafer 130, a non-uniformity could remain even if the wafer is rotated. With the cooling/heating part of the chuck not being rotated at all or being rotated at a different frequency as the wafer 130, for example, if the cooling/heating part applies a local excess cooling, such excess cooling would result in a ring signature due to the rotation of the wafer, which ring signature may then be corrected by irradiation to achieve uniform etching.

However, a non-uniformity caused by etch gas flow and most plasma non-uniformity, which represent main causes for etch non-uniformity, is made rotationally symmetric by the wafer rotation even if the heating/cooling is not made symmetrical.

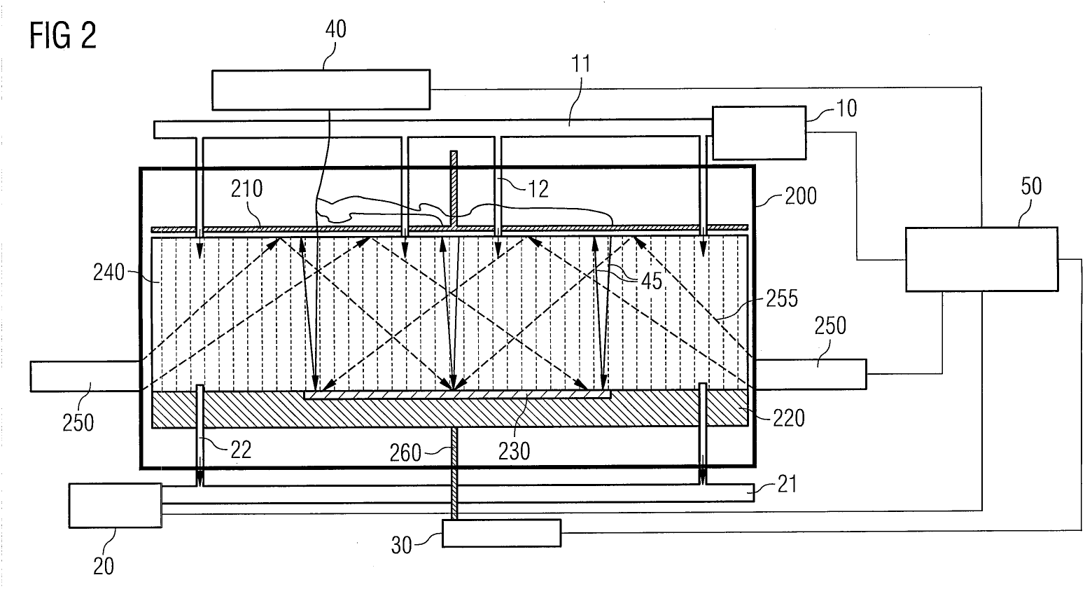

FIG. 2 shows a further embodiment of an etch chamber 200. The components are basically the same as in FIG. 1 and include a chuck 220 supporting a semiconductor wafer 230, the chuck 220 forming a lower electrode which is parallel to an upper electrode 210 of the etch chamber 200. Inside the etch chamber 200 and between electrodes 210, 220 is a gas plasma 240.

There is further provided a gas supply system 10 with a supply pipe 11 and inlet pipes 12 and a gas recycling/exhaust system 20 with an exhaust pipe 21 and outlet pipes 22.

The chuck 220 is connected to a rotatable axis 260 which is connected to a power supply and rotator 30. The rotator 30 rotates the chuck 220 and thus also the wafer 230 about axis 260 during etching. Axis 260 is identical to the central axis of the wafer 230.

Further, an in-situ etch rate measurement unit 40 may be used similar to the etch rate measurement unit 40 of FIG. 1. Measurement signals of etch rate measurement unit 40 are illustrated by arrows 45.

There are provided several irradiation sources 250 which, different to the embodiment of FIG. 1, are located at or proximate the chamber walls and indirectly illuminate the wafer 230, as is illustrated by dashed illumination arrows 255. To this end, the light is reflected at the upper electrode 210. Also, one or several mirrors may be used for the indirect illumination of the wafer. Such mirrors may be located at the chamber wall.

The radiation of the irradiation sources 250 may be infrared or optical light. In other embodiments, the radiation may be ultraviolet or deep ultraviolet. In still other embodiments the radiation may be particle radiation such as electrons. The number of illumination sources 250 may vary dependent on the kind and strength of the illumination sources and is depicted only exemplary in FIG. 2. Also, the irradiation sources 250 may be an array of individual sources and may be separately controlled in intensity and or direction.

The inner wall of the etch chamber 200 may comprise an antireflective coating. If mirrors are located at the chamber wall as discussed above, the antireflective coating would be at areas outside such mirrors.

The system further comprises a control system 50 electrically connected to the power supply and rotator 30, the irradiation sources 250, the gas supply system 10, the gas recycling/exhaust system 20 and the etch rate measurement unit 40. The control system 50 may be implemented by a computer configured to control and coordinate the functions of the respective elements of the etch chamber 200.

The function of the etch chamber 200 is similar to the function of the etch chamber 100 of FIG. 1. Different to the etch chamber 100 of FIG. 1, however, the etch chamber 200 of FIG. 2 implements an indirect/reflective illumination of the wafer. Also, it has flat dimensions. There may be shadowing effects by the indirect illumination which, however, are of advantage in some cases. In an embodiment, an array of properly tilted mirrors is provided such that the light can also hit rather perpendicular on the wafer surface. The design of FIG. 2 is suitable particularly for processes where the upper electrode 210 can be held clean such that the irradiation conditions are well controlled.

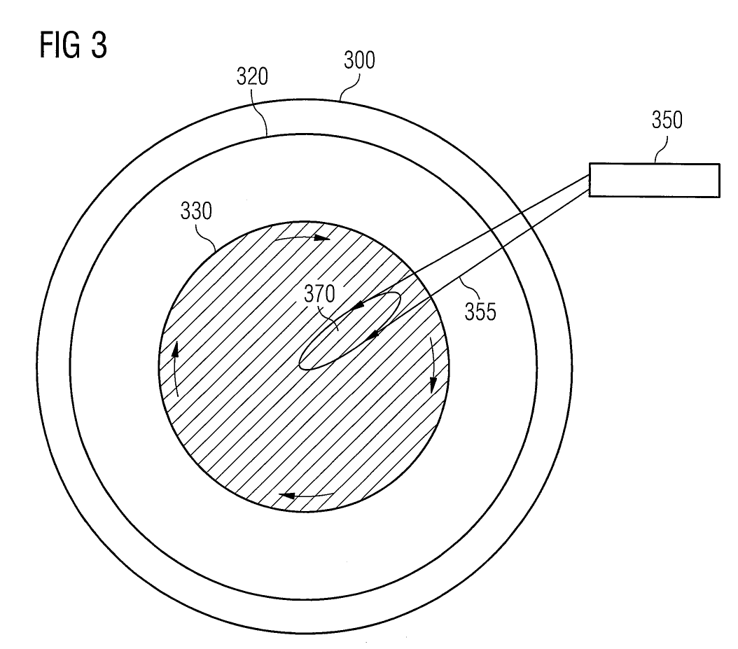

FIG. 3 shows a wafer 330 located on a chuck 320 in an etch chamber 300 similar to the embodiment of FIGS. 1 and 2. However, in the embodiment of FIG. 3, a scanning irradiation source 350 is used in combination with a rotating wafer 330.

More particularly, a scanning beam or scanning cone 355 scans a radially extending area 370 of the wafer 330 only. Such scanning may also be implemented with a fixed, non-rotating wafer 330. The scanning can also be applied by an array of mirrors where either the mirror tilt angles are scanned or the incident angles are scanned over time.

Instead of one scanning source 350, several such sources with several scanning beams or cones may be used. However, generally, the embodiment of FIG. 3 reduces the number of required irradiation sources.

In each of the embodiments of FIGS. 1 to 3, instead of having an axis 160, 260 extending through the etch chamber 100, 200 and connected to a rotator 30 located outside the etch chamber, as in illustrated in FIGS. 1 and 2, different means for rotating the chuck 120, 220, 320 and the wafer 130, 230, 330 may be provided. In one embodiment, an electric motor is located as a rotator inside the etch chamber, such that the axis rotating the chuck is also located completely inside the etch chamber. In another embodiment, the chuck includes one or several permanent magnets. Further, the rotator includes one or several rotating magnets such that rotation of the chuck is effected by magnetic interaction. In such an embodiment, a rotating axis transmitting a torque on the chuck is not required.

In an embodiment, the rotational speed of the wafer is between about 5 rpm and about 1200 rpm for a 300 mm wafer.

The combination of a rotating wafer with a scanning illumination can be implemented both with infrared or optical light (for enhancement of the etch rate by heating) and with ultraviolet or deep ultraviolet light (for enhancement of the etch rate by light assisted reactive etching and local light assisted ionization).

The wafer rotation serves to provide rotational symmetry. In the embodiment of FIG. 3, radial symmetry is achieved by the radially tuned illumination, e.g., by sweeping of the scanning beam or cone 355 (or several of such beams or cones) in a radial direction to compensate for a non-uniform etch rate in the radial direction. For example, if there is a signature of the etch rate from the center to the wafer edge such that the etch rate decreases towards the edge, an increased illumination by the scanning beam is applied towards the wafer edge to compensate for such signature. For example, the scanning beam lasts longer at areas close to the wafer edge. Accordingly, the time the radial scanning beam illuminates an area of the wafer may be a function of the radial distance of the area to the wafer center.

In all embodiments, a control system 50 may calculate an integrated irradiation intensity per wafer area required to adjust the etch effect to achieve uniform etching. The control system 50 controls the illumination source or sources to apply a corresponding irradiation to the respective wafer areas.

The electrical connection as well as cooling by fluids may be achieved by standard feed into the low pressure chamber. Fluids may be water or heat pipe fluid. More particularly, multiple ways to feed an electrical cable into the gas chamber exist. For example, an electrical cable may be fed along rotational axis 160, 260 into gas chamber 100, 200 (see FIGS. 1 and 2). In another example, an electrical cable may be fed into the gas chamber separate from the mechanical rotational elements and be connected to the chuck, e.g., by a sliding contact to bring the chuck to the desired electrical voltage. To feed cooling fluids into the gas chamber, e.g., a duct is used that comprises, e.g., a double-walled tube and a rubber seal ring. In one embodiment, the fluid ducts and the electrical duct are adapted to be non-rotating.

The basic principles discussed above may also be applied to reactive deposition processes such as reactive sputtering or Plasma Enhanced Chemical Vapor Deposition (PECVD). In reactive sputtering, a deposited film is formed by chemical reaction between a target material and a gas which is introduced into a vacuum chamber. In PECVD, thin films from a gas state are deposited to a solid state on a substrate. A uniform deposition is achieved by rotation of the wafer and/or a non-uniform irradiation that compensates for a non-uniform deposition that would be present without radiation.

The person skilled in the art will recognize that the embodiments described above are just examples and that other parameters, e.g., regarding the kind, number and location of the irradiation sources and the design of the etch chamber can be selected, depending on the manufacturing process.

What is claimed is:

1. A method of manufacturing a semiconductor device, the method comprising:
providing a semiconductor substrate;
etching the semiconductor substrate, and during etching:
rotating the substrate around an axis perpendicular to a surface of the substrate; and
irradiating the substrate non-uniformly.

2. The method according to claim 1, wherein irradiating comprises irradiating the substrate with higher intensities at areas of the substrate where an etch rate is lower.

3. The method according to claim 1, further comprising premeasuring a signature of the etching step or carrying out an in-situ measurement of the etch rate or temperature at different positions of the substrate.

4. The method according to claim 1, wherein irradiating comprises irradiating the substrate with electromagnetic radiation.

5. The method according to claim 4, wherein irradiating comprises irradiating the substrate with visible light or infrared light.

6. The method according to claim 4, wherein irradiating comprises irradiating the substrate with ultraviolet light or deep ultraviolet light.

7. The method according to claim 1, wherein irradiating comprises irradiating the substrate with particles.

8. The method according to claim 1, wherein irradiating comprises scanning the substrate with at least one scanning beam.

9. The method according to claim 1, wherein etching comprises one of plasma etching, reactive ion etching or ion etching.

10. A method of manufacturing a semiconductor device, the method comprising:
providing a semiconductor wafer;
subjecting the semiconductor wafer to a reactive deposition process or an etching step, while the semiconductor wafer is being rotated around an axis perpendicular to a surface of the semiconductor wafer.

11. The method according to claim 10, wherein the semiconductor wafer is rotated around a central axis of the semiconductor wafer.

12. The method according to claim 10, further comprising irradiating the semiconductor wafer during the reactive deposition process or etching step to enhance the deposition or etch rate, the irradiation being provided to the semiconductor wafer non-uniformly to compensate for an otherwise non-uniform deposition or etch rate.

13. The method according to claim 12, further comprising predetermining the non-uniformity of the deposition or etch rate that occurs without irradiation.

14. The method according to claim 12, wherein irradiating the semiconductor wafer comprises scanning the semiconductor wafer in a radial direction with an irradiation beam.

15. An apparatus for manufacturing of semiconductor devices, the apparatus comprising:
means for etching a semiconductor wafer;
means for rotating the semiconductor wafer around an axis perpendicular to a surface of the semiconductor wafer during etching; and
means for irradiating the semiconductor wafer non-uniformly during etching.

16. The apparatus according to claim 15, wherein the means for etching comprises an etch chamber that comprises a plasma during etching, and the means for irradiating comprises at least one source of electromagnetic radiation located in or proximate the etch chamber and different from the plasma itself.

17. The apparatus according to claim 15, wherein the means for irradiating comprises a scanner that scans the semiconductor wafer with at least one scanning beam or scanning cone.

18. The apparatus according to claim 17, wherein the scanner is adapted to scan the semiconductor wafer in a radial direction.

19. An apparatus for manufacturing of semiconductor devices, the apparatus comprising:
a chuck supporting a semiconductor wafer; and
a rotation mechanism connected to the chuck and adapted to rotate the chuck and semiconductor wafer during etching.

20. The apparatus according to claim 19, wherein the apparatus further comprises at least one irradiation source configured to irradiate the semiconductor wafer non-uniformly during etching.

21. The apparatus according to claim 20, wherein the apparatus includes an antireflective coating at least at an inner side of an etch chamber wall.

22. The apparatus according to claim 20, wherein the at least one irradiation source is located such that the semiconductor wafer is directly illuminated by radiation of the at least one irradiation source.

23. The apparatus according to claim 20, wherein the at least one irradiation source is located such that the semiconductor wafer is illuminated indirectly by the radiation of the at least one irradiation source.

24. The apparatus according to claim 20, wherein the at least one irradiation source comprises a scanner adapted to illuminate the semiconductor wafer in a radial direction with a scanning beam or scanning cone.

25. An etch chamber for manufacturing of semiconductor devices, the etch chamber comprising:
an etch chamber having a wall;
a gas supply system to supply gas to the etch chamber;
a gas exhaust system to exhaust gas from the etch chamber;
a pair of parallel electrodes, within the etch chamber, the electrodes adapted to produce a gas plasma inbetween;
a chuck adopted to support a semiconductor wafer in the etch chamber;
a rotation mechanism connected to the chuck and adapted to rotate the chuck and semiconductor wafer during etching; and
at least one irradiation source different from the gas plasma configured to irradiate the semiconductor wafer non-uniformly during etching.
